(19) United States
(12) Patent Application Publication
(10) Pub. No.: US 2007/0182421 A1
(43) Pub. Date: Aug. 9, 2007

(54) APPARATUS FOR DETECTING AN ATTACK ON AN ELECTRIC CIRCUIT

(75) Inventors: MARCUS JANKE, Munich (DE); Peter Laackmann, Munich (DE)

Correspondence Address: DICKSTEIN SHAPIRO LLP, 1177 AVENUE OF THE AMERICAS 6TH AVENUE, NEW YORK, NY, 10036-2714, US

(73) Assignee: INFINEON TECHNOLOGIES AG, Munich (DE)

(21) Appl. No.: 11/671,182

(22) Filed: Feb. 5, 2007

(30) Foreign Application Priority Data
Feb. 3, 2006 (DE) 10 2006 005 053.3

(51) Int. Cl. G01R 31/08

(52) U.S. Cl. 324/522

(57) ABSTRACT

An apparatus for detecting an attack on an electric circuit, wherein the electric circuit includes a current consumption threshold value discriminator to determine whether current consumption of the electric circuit exceeds a predetermined threshold value or not, and to generate a binary current limitation signal depending therefrom. The apparatus includes a monitor for monitoring the binary current limitation signal over a predetermined time interval, in order to indicate a signal characterizing the current consumption of the electric circuit over the predetermined time interval, and a detector for detecting an attack on the electric circuit based on the monitoring signal.

### CROSS-REFERENCE TO RELATED APPLICATION

This application claims priority from German Patent Application No. 10 2006 005 053.3, which was filed on Feb. 03, 2006, and is incorporated herein by reference in its entirety.

### BACKGROUND

1. Field of the Invention:

The present invention relates to an apparatus for detecting an attack on an electric circuit, and particularly to an apparatus for detecting an attack on an electric circuit determining an attack based on a current consumption of the electric circuit.

2. Description of the Related Art:

Security controllers are increasingly employed in a series of applications, such as chip card ICs (integrated circuits), that is chips or semiconductor devices with integrated circuitry.

The security controllers are employed to execute a security-relevant operation, such as authentication of a user, on a chip card IC, such as a money card IC, for example.

If a security controller is employed in a certain application, its current consumption in predetermined limited program blocks or blocks of an execution program performed over a predetermined time interval is mostly very similar, dependent on whether e.g. the crypto-coprocessor is or runs in a switched-on operating state here, or an EEPROM (electrical erasable programmable read-only memory) is being programmed. But if a chip is operated under attack conditions, the current consumption may change significantly by the fact that in a DFA (differential failure analysis) attack the crypto-coprocessor is activated via a high number of successive activation events or many thousands of times directly one after the other.

In this, the overall current consumption may even increase by an order of magnitude or factor of 10 through leakage currents in an attack by means of X radiation. This change in current consumption may be used as a detection for attacks, but with the detection being relatively difficult to realize. One possible approach to detect an attack is to directly determine current consumption of a security controller, such as via a voltage drop at a resistor or an output signal at a voltage regulator. But this approach is accompanied by great effort or high chip area need or high additional area to implement the functionality on the chip, or the above-mentioned approach is difficult to realize technically.

### BRIEF DESCRIPTION OF THE DRAWING

FIG. 1 shows a chip with an electric circuit and an apparatus for detecting an attack on the electric circuit according to one embodiment of the present invention.

### DESCRIPTION OF THE INVENTION

The present invention provides an apparatus for detecting an attack on an electric circuit, which enables secure detection of an attack on the electric circuit at reasonable effort.

In accordance with a first aspect, the present invention provides an apparatus for detecting an attack on an electric circuit, wherein the electric circuit has a current consumption threshold value discriminator formed to determine whether current consumption of the electric circuit exceeds a predetermined threshold value and to generate a binary current limitation signal having a first binary value if the current consumption falls below the predetermined threshold value, and a second binary value if the current consumption exceeds the predetermined threshold value, the apparatus having: a monitor for monitoring the binary current limitation signal over a predetermined time interval to indicate a monitoring signal characterizing the current consumption of the electric circuit over the predetermined time interval; and a detector for detecting an attack on the electric circuit based on the monitoring signal.

In accordance with a second aspect, the present invention provides a method of detecting an attack on an electric circuit by: determining whether current consumption of the electric circuit exceeds a predetermined threshold value; generating a binary current limitation signal having a first binary value if the current consumption falls below the predetermined threshold value, and a second binary value if the current consumption exceeds the predetermined threshold value; monitoring the binary current limitation signal over a predetermined time interval; generating a monitoring signal characterizing the current consumption of the electric circuit over the predetermined time interval; and detecting an attack on the electric circuit based on the monitoring signal.

In accordance with a third aspect, the present invention provides a digital storage medium, in particular floppy disk, with electronically readable control signals capable of interacting with a programmable computer system so that a method of detecting an attack on an electric circuit is executed, the method having the steps of: determining whether current consumption of the electric circuit exceeds a predetermined threshold value; generating a binary current limitation signal having a first binary value if the current consumption falls below the predetermined threshold value, and a second binary value if the current consumption exceeds the predetermined threshold value; monitoring the binary current limitation signal over a predetermined time interval; generating a monitoring signal characterizing the current consumption of the electric circuit over the predetermined time interval; and detecting an attack on the electric circuit based on the monitoring signal.

In accordance with a fourth aspect, the present invention provides a computer program product with program code stored on a machine-readable carrier for performing, when the computer program product is executed on a computer, a method of detecting an attack on an electric circuit by: determining whether current consumption of the electric circuit exceeds a predetermined threshold value; generating a binary current limitation signal having a first binary value if the current consumption falls below the predetermined threshold value, and a second binary value if the current consumption exceeds the predetermined threshold value; monitoring the binary current limitation signal over a predetermined time interval; generating a monitoring signal characterizing the current consumption of the electric circuit over the predetermined time interval; and detecting an attack on the electric circuit based on the monitoring signal.

In accordance with a fifth aspect, the present invention provides a computer program with program code for performing, when the program is executed on a computer, a method of detecting an attack on an electric circuit by: determining whether current consumption of the electric circuit exceeds a predetermined threshold value; generating a binary current limitation signal having a first binary value if the current consumption falls below the predetermined threshold value, and a second binary value if the current consumption exceeds the predetermined threshold value; monitoring the binary current limitation signal over a predetermined time interval; generating a monitoring signal characterizing the current consumption of the electric circuit over the predetermined time interval; and detecting an attack on the electric circuit based on the monitoring signal.

The present invention provides an apparatus for detecting an attack on an electric circuit, wherein the electric circuit comprises a current consumption threshold value means formed to determine whether a current consumption of the electric circuit exceeds a predetermined threshold value, and to generate a binary current limitation signal, which has a first binary value if the current consumption falls below the predetermined threshold value, and has a second binary value if the current consumption exceeds the predetermined threshold value, wherein the apparatus comprises means for monitoring the binary current limitation signal over a predetermined time interval to indicate a monitoring signal characterizing the current consumption of the electric circuit over the predetermined time interval, and means for detecting an attack on the electric circuit based on the monitoring signal.

The present invention is based on the finding that, for the recognition of an attack on an electric circuit, it is not necessary to determine the exact current consumption course, but that it rather is sufficient to restrict the monitoring to a binary current limitation signal, the value of which varies depending on whether the current consumption of the circuit exceeds a predetermined threshold value or the current consumption of the circuit falls below the predetermined threshold value. In this manner, safe attack detection with reasonable effort can be achieved.

For example, one advantage of the present invention is that such a binary current limitation signal is already available in some security controllers, to be used for clock rate control or for the control of the current consumption. Such arrangements already generate signals if a predetermined current consumption is exceeded, and thus cause the processor of the security controller to work more slowly and hence consume less current. In the case of these security controllers, the retrofit to implement the present invention is easy, because only monitoring means for monitoring the binary current limitation signal over the predetermined time interval, in order to output the characteristic monitoring signal, and means for detecting an attack based on the monitoring signal still have to be provided.

According to one embodiment of the present invention, a counter connected to the current limitation signal and counting or adding the binary states in which the current limitation signal assumes one or the other binary state within a certain time unit, functions as monitoring means to capture an energy profile of a certain time interval. In this case, the monitoring means is hence formed by a counter, which is counted up by the pulses of the current limitation and can be read out after the elapse of a certain time interval. Hence, an energy profile may be captured and evaluated in the operation of a security controller. If the profile no longer corresponds to the originally measured one, an attack attempt or attack can be detected with this.

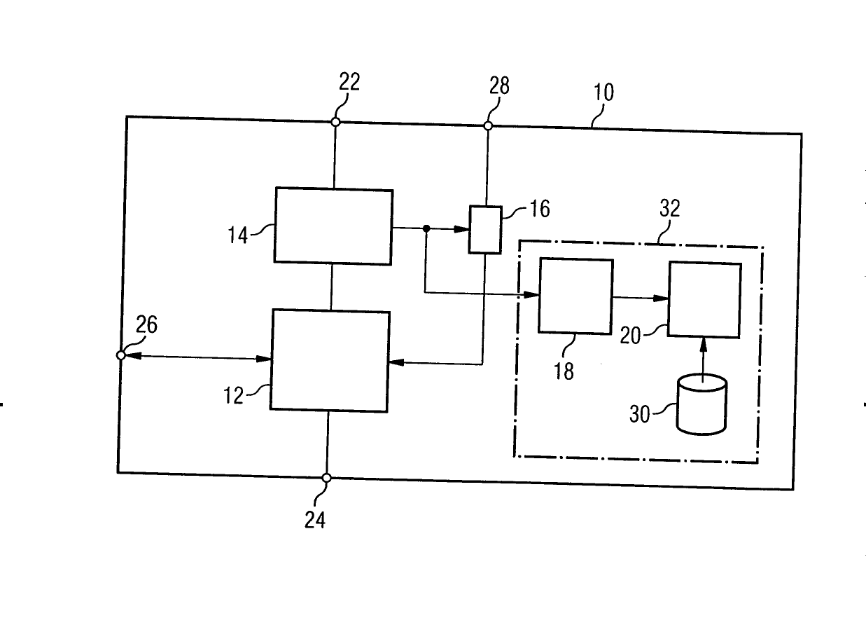

FIG. 1 shows a chip 10, in which an apparatus for detecting an attack on an electric circuit according to an embodiment of the present invention is implemented. The chip 10 includes processing means 12, current threshold value monitoring means 14, a clock interrupter 16, monitoring means 18, and alerting means 20. Furthermore, the chip 10 includes a supply voltage terminal 22, a ground terminal 24, a data input/output 26, and a clock terminal 28. In addition, memory 30 for providing a reference monitoring signal is provided.

The processing means 12 is connected to the data input/output 26 and capable of exchanging data with an external device (not shown), such as a terminal, via the same. The processing means 12 is for example provided as an arrangement of processor and coprocessors. The processing means 12, above all, takes over the tasks of the chip 10 and implements the desired functionalities with respect to the communication with the external device, such as authentication tasks, encryption tasks, debiting tasks and the like, in connection with a terminal session with a terminal coupled to the input/output 26.

During the data processing or the fulfillment of its tasks, the processing means 12 is supplied with voltage via the supply voltage terminal 22 and the ground terminal 24. To this end, the processing means 12 is connected between the supply voltage terminal 22 and the ground terminal 24. Depending on which task the processing means 12 is fulfilling at the moment, such as encryption or awaiting a reply of the external device, the momentary current consumption of the processing means 12 varies.

The current consumption threshold value monitoring means 14 is coupled to a supply path connecting the processing means 12 to the terminals 22 and 24. It may for example be connected in series into this supply path, as it is shown in FIG. 1. The current consumption threshold value monitoring means 14 is formed such that it monitors the momentary current consumption of the processing means 12 upon whether the same falls below or exceeds a certain current consumption threshold value, in order to output a binary current limitation signal, which has a logically high or logically low state, at its output depending on conditions. In the following, it will be assumed that the current limitation signal, which is output from means 14, has a logically high state if the momentary current consumption exceeds the predetermined threshold value, and otherwise a logically low state.

The clock interruption means 16 is connected between the clock terminal 28 and a clock input of the processing means 12. The processing means 12 performs the data processing with the clock given to it by a clock signal at its clock input. For example, the processing means 12 is formed such that the momentary current consumption rises if the processing means 12 works with a faster clock, and falls if it works with a slower clock. The chip 10 is for example implemented in CMOS technology, in which every switching process of internal transistors leads to current consumption, so that a higher clock rate entails higher current consumption of the processing means 12.

Moreover, the clock interruption means 16 comprises a control input coupled to the current consumption threshold value monitoring means 14 to obtain the binary current limitation signal therefrom and, depending on whether the binary current limitation signal has a logically high or a logically low state, let the clock signal pass from the clock terminal 28 to the clock input of the processing means 12 or to interrupt the clock signal so as not to let it pass to the means 12. In particular, the means 16 interrupts the clock signal if the binary current limitation signal of the means 14 indicates that the present current consumption of the means 12 exceeds the predetermined threshold value or has a logically high state. The means 14 and 16 thus implement a current limitation functionality of the chip 10 by limiting or restricting the current consumption of the processing means 12 to about maximally the current consumption threshold value of the means 14.

The further components of the chip 10, namely the monitoring means 18, the alerting means 20, and the memory 30, form that part of the chip 10 forming the apparatus for detecting an attack on the chip 10 or the electric circuit implemented therein, with this part being denoted with the reference numeral 32 in FIG. 1. In particular, the monitoring means 18 monitors the binary current limitation signal from the means 14 and outputs, as a result, a monitoring signal to the alerting means 20, which has been deduced from observation of the binary current limitation signal over a predetermined time interval and thus represents a monitoring signal characteristic for the current consumption of the processing means 12 over the predetermined time interval.

The alerting means 20 is provided to compare the monitoring signal from the monitoring means 18 to a reference monitoring signal it obtains from the memory 30. If the two signals do not have a predetermined relation to each other or do not satisfy a predetermined condition, such as a condition that the two signals must not deviate from each other by more than a predetermined percentage, the alerting means 20 outputs an alarm signal to an action means, which for example interrupts the current consumption for the processing means 12 upon the alarm signal, prevents the processing means 12 from any further data output, places the processing means 12 into an idle state, or the like.

The functionality of the chip 10 with respect to the attack detection is to be discussed in still some more detail in the following. As it has already been described previously, the processing means 12 consumes a different amount of current when fulfilling the different tasks in computation-intensive tasks. The means 14 therefore outputs a binary current limitation signal with a logically high state more frequently, so that the interruption means 16 interrupts the clock signal 28 more frequently in these cases. In this manner, the binary current limitation signal is in a way characteristic for the tasks currently executed by the processing means 12.

But also a manipulative attack on the chip 10 or the processing means 12 has further influence on the current limitation signal or the current consumption of the processing means 12. Ionizing radiation, for example, which is used to disturb the computation operations of the processing means 12 and force it to wrong results, may for example be used by potential attackers to gain access to secret data, which are processed by the processing means 12, such as secret keys or the like, or to trigger sensitive functions, such as a debiting function, by means of DFA (differential fault attack) attacks.

Instead of immediately evaluating the current consumption, the current detection apparatus 32 or the monitoring means 18 only uses the binary current limitation signal, which at an increased rate has a logically high state, i.e. a state indicating that the present current consumption of the processing means 12 exceeds the threshold value, in the case of manipulation or invasive attacks, as it has been described previously, relative to a state of absence of an attack.

Means 18 is provided to monitor or capture the binary current limitation signal over a predetermined time interval and form a characteristic current monitoring signal therefrom. To this end, the monitoring means 18 is for example formed as a counter directly clocked with the binary current limitation signal, in order to count, over the predetermined time interval, the number of phases in which the binary current limitation signal continuously occupies the logically high state, or in which the same occupies the logically low state. As an alternative, the monitoring means 18 may be provided as a counter controlled with a clock to increment/decrement the current counter value depending therefrom, wherein this clock has been obtained from the binary current limitation signal by a temporally equidistant sampling, such as by sampling by means of the clock signal, as it is present at the clock terminal 28, i.e. at the input of the clock interruption means 16.

However, other possibilities also exist. The current monitoring means 18 could also integrate the binary current limitation signal also in analog manner over the predetermined time interval, in order to digitize the analog integration result, for example. Furthermore, the monitoring means 18 could be formed as a type of coding means, which codes a series of binary ones and zeros obtained from the previously described equidistant sampling of the binary current limitation signal by means of run length coding or the like, for example, and determines and outputs a monitoring signal from the result. In particular, the monitoring signal could indicate the relation between the time proportions in which the binary current limitation signal occupied the binary state one over the predetermined time interval or the current limitation signal occupied the value zero over the predetermined time interval.

Alternatively or additionally, the monitoring means could further determine a statistic about the mean duration or a mean value of the duration or the length of the individual phases in which the binary current limitation signal uninterruptedly occupied a binary one or binary zero.

In the memory 30, now corresponding reference monitoring signals or a corresponding reference monitoring signal are/is stored, which are/is comparable with the monitoring signal of the means 18. A reference monitoring signal in the memory 30 for example is a target counter reading the monitoring means 18 should or would have at the end of the predetermined time interval if no attack has taken place. In the case of more complex monitoring signals, the reference monitoring signal in the memory 30 is also more complex. In the previously mentioned exemplary embodiment of a monitoring signal indicating the relation of the duration of the 1- and 0-phases, the reference monitoring signal for example includes two quantities, namely the amount of one-samplings within the predetermined time interval on the one hand and the mean length of the one sample runs within the predetermined time interval on the other. The corresponding statistics are determined from the current limitation signal by the means 18, also the determination by the alerting means 20 from the monitoring signal would also be possible, in order to compare the same to the reference monitoring signal from the memory 30.

The alerting means 20 then outputs the alert signal if the values to be compared for example deviate from each other by more than a predetermined tolerance, wherein the measures, which may be taken upon the alert signal, have already been described exemplarily in the foregoing. As it has already been discussed previously, the current consumption characteristic of the processing means 12 is different depending on which task it is fulfilling at the moment. According to one embodiment of the present invention, therefore different reference monitoring signals are stored in the memory 30 for different tasks of the processing means 12, for example. In the course of the fulfillment of a certain task by the processing means 12, the monitoring means 18 therefore forms the monitoring signal over a predetermined time interval, wherein the alerting means 20 compares the then-developing monitoring signal to that reference monitoring signal corresponding to the corresponding task.

The triggering of when the monitoring means 18 begins the monitoring or the formation of the monitoring signal may be established in different manner. For example, in the program code executed by the processing means 12, command lines are provided, which activate the monitoring means 18 or let the predetermined time interval begin on the one hand, and establish the reference monitoring signal from the memory 30 to be used, on the other hand. In this case, the programmer has to ensure that the command lines appear at the corresponding lines in the program in which the processing means 12 fulfills the respective predetermined task in the program flow. In this case the processing means 12 activates the monitoring means 18 via a line not shown in FIG. 1. The trigger commands could be specially provided command or also jump command to predetermined addresses or commands addressing certain CPU registers, in order to stimulate coprocessors to perform longer computation tasks.

As an alternative, the processing means 12 for example disposes of a corresponding register into which corresponding values indicating the processing means task to be fulfilled presently may be entered via command lines, which the means 20 always accesses when a new characteristic monitoring signal from the means 18 is to be compared to a reference monitoring signal, in order to use the right reference monitoring signal from the memory 30 on the basis of the task indicated.

The reference monitoring signals in the memory 30 are preferably filed there prior to the issue of the chip 10, such as prior to the chip card issue if the chip 10 is integrated in a chip card, by the monitoring means 18 forming the monitoring signal either by simulation or by a test run during the respective task of the processing means 12. These monitoring signals then form the reference signals, since no attack or no attack situation is present in the test run by default.

According to the previous embodiment of the present invention, the processing means 12, the current threshold value monitoring means 14, the clock interrupter 16, the monitoring means 18, the alerting means 20, and the memory 30 are integrated on the chip 10 together. But any implementations of a circuit including the elements 12, 14, 16, 18, 20, 30 mentioned, such as also on several chips or in a discrete circuit, are alternatives hereto.

In the chip 10, the processing means 12 was implemented as a logic circuit, but the processing means 12 could also be implemented as a memory with access control, or as any circuit element preferably having increased current consumption at an attack thereon.

On the chip 10, a supply terminal 22, a data input/output 26 and a clock terminal 28 were arranged, but the supply voltage terminal 22 and the data input/output 26 and the clock terminal 28 could alternatively be implemented as a single terminal via which the processing means 12 communicates with the external means by contact or without contact, is clocked, and is energized at the same time. Or alternatively, the supply voltage terminal 22 and the input/output 26, the supply voltage terminal 22 and the clock 28, or the input terminal 26 and the clock terminal 28 could also be implemented in a single terminal. A provision of the clock with which the processing means 12 is clocked via an internal oscillator arranged on the chip 10 according to the present invention would also be possible.

The current threshold value monitoring means 14 may for example be implemented as a comparator comparing a voltage drop at sense resistor connected into the supply path to a predetermined value and outputting the current limitation signal depending therefrom. Alternatives hereto, however, are any means capable of determining exceeding or falling below a current consumption of the processing means 12 or the chip 10.

In the chip 10, a current consumption of the processing means 12 was reduced, when the current consumption exceeds the predetermined threshold value, by interrupting a connection between the clock terminal 28 and the processing means 12 by the clock interrupter 16. The clock interrupter 16 could here be implemented as any switch, such as a field effect transistor, which is controlled by the current limitation signal, but any other means capable of interrupting a connection between the clock signal terminal 28 and the processing means 12 when the current consumption exceeds the predetermined threshold value or, if necessary, even only reduce the clock rate when the current consumption exceeds the predetermined threshold value, are alternatives hereto. Even any means reducing current consumption of the chip 10 if the current limitation signal indicates that the current consumption has exceeded the predetermined threshold value are possible.

In the chip 10 according to the present invention, the monitoring means 18 was exemplarily described as a counter counting the number of phases in which the current limitation signal has the logically high state, or implemented as an integrator integrating over the current limitation signal over a predetermined time interval and outputting the integration result in digital form. However, an output of the integration result in form of an analog signal the level of which depends on the integration result is also possible. As an alternative hereto, the current monitoring means 18 could be implemented as any means monitoring the binary current limitation signal over a predetermined time interval and outputting a current monitoring signal characterizing the current consumption of the electric circuit over the predetermined time.

The current monitoring means 18 determines the elapse of the predetermined time interval for example by being activated by the processing means at the beginning of the predetermined time interval and deactivated at the end of the predetermined time interval. As an alternative hereto, however, the current monitoring means 18 could be connected to the clock terminal 28, so that it determines the predetermined time interval from the fact that a certain amount of clock cycles has elapsed. Or an oscillator could alternatively be integrated in the current monitoring means 18, wherein in the monitoring means could then determine the predetermined time interval from the fact that a certain number of oscillator cycles has elapsed. Alternatives hereto are, however, any means indicating elapse of the predetermined time interval or predetermined time duration to the current monitoring means 18.

In the chip 10 according to the present invention, the detecting means 20 exemplarily compares a counter reading of the current monitoring means 18 to a predetermined value or an integration result communicated from the current monitoring means 18 to a predefined value for the integration result, in order to detect an attack on the chip 10. But any means detecting an attack on the chip 1 based on the current monitoring signal are possible.

In the chip 10 according to the present invention, the detecting means 20 compared one piece of information from the current monitoring signal, such as a value of the counter reading, to a value deposited in the memory 30, or the detecting means 20 compared the current monitoring signal to a reference signal made available from the memory 30, and determined therefrom whether an attack on the circuit has taken place. Alternatives hereto are, however, any forms of information filed in the memory 30 and enabling a comparison to the detecting means 20, and enabling a decision therefrom, whether an attack on the chip 10 according to the present invention has taken place or not.

In the chip 10 according to the present invention, the current limitation signal has a logically high state if the current consumption of the processing means 12 or the current consumption of the chip exceeds the predetermined threshold value, and a logically low state if the current consumption does not exceed the predetermined threshold value. As an alternative hereto, the current limitation signal could, however, also have a logically low state if the current consumption of the processing means exceeds the predetermined threshold value, and a logically high state if the current consumption does not exceed the predetermined threshold value.

Depending on the conditions, the inventive method of detecting an attack may be implemented in hardware or in software. The implementation may be on a digital storage medium, in particular a floppy disk, an EEPROM (electrical erasable programmable read-only memory) memory, an EPROM (erasable programmable read-only memory) memory, a DVD or a CD, with electronically readable control signals capable of interacting with a programmable computer system so that the corresponding method is executed. In general, the invention thus also consists in a computer program product with a program code stored on a machine-readable carrier for performing the inventive method, when the computer program product is executed on a computer. In other words, the invention may thus be realized as a computer program with a program code for performing the inventive method, when the computer program is executed on a computer.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. An apparatus for detecting an attack on an electric circuit, wherein the electric circuit comprises a current consumption threshold value discriminator formed to determine whether current consumption of the electric circuit exceeds a predetermined threshold value and to generate a binary current limitation signal having a first binary value if the current consumption falls below the predetermined threshold value, and a second binary value if the current consumption exceeds the predetermined threshold value, the apparatus comprising:
a monitor for monitoring the binary current limitation signal over a predetermined time interval and outputting a monitoring signal characterizing the current consumption of the electric circuit over the predetermined time interval; and
a detector for detecting an attack on the electric circuit based on the monitoring signal.

2. The apparatus of claim 1, wherein the monitor comprises an integrator for integrating the current limitation signal during the predetermined time interval to obtain an integration result and for outputting the monitoring signal depending on the integration result.

3. The apparatus of claim 1, wherein the detector compares a level of the monitoring signal to a level of a reference signal, and indicates an attack on the electric circuit depending on the comparison, or indicates that no attack on the electric circuit has taken place.

4. The apparatus of claim 1, wherein the monitor comprises a counter for incrementing or decrementing a counter reading depending on the current limitation signal and outputting the monitoring signal based on the counter reading.

5. The apparatus of claim 1, wherein the detector performs a determination whether an attack is present based on a comparison of the monitoring signal to a reference signal.

6. The apparatus of claim 5, wherein the electric circuit comprises a processor for performing a plurality of predetermined operations, and wherein detector receives a piece of information on the predetermined operation and selects a course of the reference signal from a plurality of reference courses based on the piece of information on the predetermined operation.

7. The apparatus of claim 1, further comprising a current limiter, which is connected between a clock signal terminal and a further terminal of the circuit, for receiving the binary current limitation signal and interrupting supply of the clock signal to the electric circuit if the binary current limitation signal has the second binary value and allowing the clock signal pass to the electric circuit if the binary current limitation signal has the first binary value.

8. The apparatus of claim 1, wherein the monitor determines a mean duration of individual phases in which the binary current limitation signal uninterruptedly occupies a particular binary value.

9. A method of detecting an attack on an electric circuit, comprising:
determining whether current consumption of the electric circuit exceeds a predetermined threshold value;
generating a binary current limitation signal having a first binary value if the current consumption falls below the predetermined threshold value, and a second binary value if the current consumption exceeds the predetermined threshold value;
monitoring the binary current limitation signal over a predetermined time interval;
generating a monitoring signal characterizing the current consumption of the electric circuit over the predetermined time interval; and
detecting an attack on the electric circuit based on the monitoring signal.

10. A digital storage medium with electronically readable control signals capable of interacting with a programmable computer system so that a method of detecting an attack on an electric circuit is executed, the method comprising:
determining whether current consumption of the electric circuit exceeds a predetermined threshold value;
generating a binary current limitation signal having a first binary value if the current consumption falls below the predetermined threshold value, and a second binary value if the current consumption exceeds the predetermined threshold value;
monitoring the binary current limitation signal over a predetermined time interval;
generating a monitoring signal characterizing the current consumption of the electric circuit over the predetermined time interval; and
detecting an attack on the electric circuit based on the monitoring signal.

11. A computer program product with program code stored on a machine-readable carrier for performing, when the computer program product is executed on a computer, a method of detecting an attack on an electric circuit, comprising:
determining whether current consumption of the electric circuit exceeds a predetermined threshold value;
generating a binary current limitation signal having a first binary value if the current consumption falls below the predetermined threshold value, and a second binary value if the current consumption exceeds the predetermined threshold value;
monitoring the binary current limitation signal over a predetermined time interval;
generating a monitoring signal characterizing the current consumption of the electric circuit over the predetermined time interval; and
detecting an attack on the electric circuit based on the monitoring signal.

12. A computer program with program code for performing, when the program is executed on a computer, a method of detecting an attack on an electric circuit, comprising:
determining whether current consumption of the electric circuit exceeds a predetermined threshold value;
generating a binary current limitation signal having a first binary value if the current consumption falls below the predetermined threshold value, and a second binary value if the current consumption exceeds the predetermined threshold value;
monitoring the binary current limitation signal over a predetermined time interval;
generating a monitoring signal characterizing the current consumption of the electric circuit over the predetermined time interval; and
detecting an attack on the electric circuit based on the monitoring signal.

13. An apparatus for detecting an attack on an electric circuit, wherein the electric circuit comprises a current consumption threshold value discriminator formed to determine whether current consumption of the electric circuit exceeds a predetermined threshold value and to generate a binary current limitation signal having a first binary value if the current consumption falls below the predetermined threshold value, and a second binary value if the current consumption exceeds the predetermined threshold value, the apparatus comprising:
a monitoring means for monitoring the binary current limitation signal over a predetermined time interval and for outputting a monitoring signal characterizing the current consumption of the electric circuit over the predetermined time interval; and
a detecting means for detecting an attack on the electric circuit based on the monitoring signal.

14. The apparatus of claim 13, further comprising a current limiting means, which is connected between a clock signal terminal and a further terminal of the circuit, for receiving the binary current limitation signal and interrupting supply of the clock signal to the electric circuit if the binary current limitation signal has the second binary value and for allowing the clock signal to pass to the electric circuit if the binary current limitation signal has the first binary value.
